(19) United States
(12) Patent Application Publication
(10) Pub. No.: US 2008/0089033 A1
(43) Pub. Date: Apr. 17, 2008

(54) Thermal conductive medium cover

(75) Inventors: Szu-Yuan Lu, Chung-Ho City (TW); Rui-Xia Hu, HuiZhou (CN)

Correspondence Address: RABIN & Berdo, PC, 1101 14TH STREET, NW, SUITE 500, WASHINGTON, DC, 20005, US

(73) Assignee: Cooler Master Co., Ltd., Taipei Hsien (TW)

(21) Appl. No.: 11/907,469

(22) Filed: Oct. 12, 2007

(30) Foreign Application Priority Data
Oct. 13, 2006 (TW) 095218127

(51) Int. Cl. H05K 7/20

(52) U.S. Cl. 361/720; 174/163 R

(57) ABSTRACT

A thermal conductive medium cover is covered on the bottom of a heat sink for protecting a thermal conductive medium on the bottom of the heat sink, and is latched by a latching member for the heat sink. The thermal conductive medium cover includes a tray body covered on the bottom of the heat sink for protecting the thermal conductive medium, and two latched portions formed on two opposite lateral edges of the tray body. Two ends of the latching member respectively latch the two latched portions, so as to fix the tray body to the bottom of the heat sink. Thus, the thermal conductive medium cover is firmly fixed and will not fall off. Meanwhile, the latching member is also fixed and will not shake relative to the heat sink, thus preventing the latching member from colliding with the heat sink.

### CROSS-REFERENCE TO RELATED APPLICATIONS

This non-provisional application claims priority under 35 U.S.C. §119(a) on Patent Application No(s). 095218127 filed in Taiwan, R.O.C. on Oct. 13, 2006, the entire contents of which are hereby incorporated by reference.

### BACKGROUND OF THE INVENTION

1. Field of Invention

The present invention relates to a thermal conductive medium cover, and more particularly to a thermal conductive medium cover that can be fixed on the bottom of the heat sink by a latching member for the heat sink.

2. Related Art

To reduce the thermal contact resistance between a heat sink and a heat source such as a chip, a thermal conductive medium as known as thermal is usually disposed between the heat sink and the heat source to fill up the space there-between, so as to reduce the thermal contact resistance and enhancing the thermal conductivity from the heat source to the heat sink. For the convenience, after the heat sink is fabricated, a paste-like, colloidal, or solid flaky thermal conductive medium is first attached to the bottom of the heat sink. Thus, when the heat sink is fixed onto the heat source, there is no need to coat the thermal conductive medium. However, to protect the thermal conductive medium and prevent the thermal conductive medium from being stained or fall off during the delivery of the heat sink, a thermal conductive medium cover is disposed and covered on the bottom of the heat sink, for protecting the thermal conductive medium.

Referring to FIG. 1, a thermal conductive medium cover 1 in the prior art is covered on the bottom of a heat sink 2, for protecting a thermal conductive medium 3 attached to the bottom of the heat sink 2.

However, as the thermal conductive medium cover 1 in the prior art is only fixed onto the bottom of the heat sink 2 by tight fit, the fixing force is limited. The cover 1 may fall off during the delivery of the heat sink 2, and cannot provide protection for the thermal conductive medium 3. Therefore, it has become an important technical issue how to enhance the fixing force for the thermal conductive medium cover.

Moreover, currently, many heat sinks 2 has a latching member 4 assembled thereon, for the convenience of using the latching member 4. Meanwhile, the problem that the latching member 4 may fall off and get lost when the latching member 4 is detached from the heat sink 2 can be avoided. During the delivery of the heat sink 2, the latching member 4 that is not fixed may shake relative to the heat sink 2 when moving the heat sink 2. The shake of the latching member 4 will inevitably cause the collision between the latching member 4 and the heat sink 2, thus resulting in deformations of the fins or damages to the thermal conductive structures such as heat pipes. Therefore, it is another technical problem in urgent need of being solved how to alleviate the shaking of the latching member.

### SUMMARY OF THE INVENTION

In the prior art, the fixing force for fixing the thermal conductive medium cover to the bottom of the heat sink is limited, and the cover may easily fall off. Besides, the latching member of the heat sink, not fixed or retained, may easily shake and collide with the heat sink, resulting in damages to the heat sink. In view of the above problems, the object of the present invention is to provide a thermal conductive medium cover, which can be latched by a latching member of a heat sink, for enhancing the fixing force for fixing the thermal conductive medium cover to the bottom of the heat sink, and making sure the latching member is also fixed without shaking.

In order to achieve the above object, a thermal conductive medium cover of the present invention is provided. The thermal conductive medium cover is covered on the bottom of a heat sink for protecting a thermal conductive medium on the bottom of the heat sink, and is fixed by a latching member for the heat sink. The thermal conductive medium cover has a tray body covered on the bottom of the heat sink for protecting the thermal conductive medium, and two latched portions formed on two opposite lateral edges of the tray body. Two ends of the latching member respectively latch the two latched portions, so as to fix the tray body to the bottom of the heat sink. Through the fixing of the latching member, the tray body of the thermal conductive medium cover is firmly fixed to the bottom of the heat sink.

The advantage of the present invention is that the fixing force for the thermal conductive medium cover is enhanced by the use of a latching member, and meanwhile the latching member is also fixed without shaking, so as to prevent the thermal conductive medium cover from falling off and to prevent the latching member from colliding with the heat sink during the delivery.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1 is perspective view of a thermal conductive medium cover covered on the bottom of a heat sink in the prior art;

FIG. 2A is an exploded view of a thermal conductive medium cover detached from a heat sink of a first embodiment of the present invention;

FIG. 2B is a perspective view of the thermal conductive medium cover covered on the bottom of the heat sink of the first embodiment of the present invention;

FIG. 3 is a cross-sectional view of the first embodiment;

FIGS. 4A and 4B are partial enlarged views showing one end of the latching member and the latched portion on one side of the tray body of the first embodiment;

FIGS. 5A and 5B are partial enlarged views showing the other end of the latching member and the latched portion on the other side of the tray body of the first embodiment;

FIG. 6 is a cross-sectional view showing the heat sink and the thermal conductive medium cover accommodated in a package of the first embodiment of the present invention;

FIGS. 7A and 7B are partial enlarged views showing a latched portion of a thermal conductive medium cover of a second embodiment of the present invention;

FIGS. 8A and 8B are partial enlarged views showing one end of a latching member and a latched portion on one side of a tray body of a third embodiment of the present invention;

FIG. 8C is a partial enlarged views showing the other end of the latching member and the latched portion on the other side of the tray body of the third embodiment;

FIG. 8D shows another latching relation between the handle and the latched portion of the third embodiment;

FIGS. 9A and 9B are partial enlarged views showing a latched portion of a thermal conductive medium cover of a fourth embodiment of the present invention;

FIG. 10 is a partial enlarged views showing a latched portion of a thermal conductive medium cover of a fifth embodiment of the present invention;

FIGS. 11A and 11B are partial enlarged views showing a latched portion a thermal conductive medium cover of a sixth embodiment of the present invention; and

FIGS. 12A and 12B are partial cross-sectional views showing latched portions of different configurations and a second fixing latching member of a seventh embodiment of the present invention.

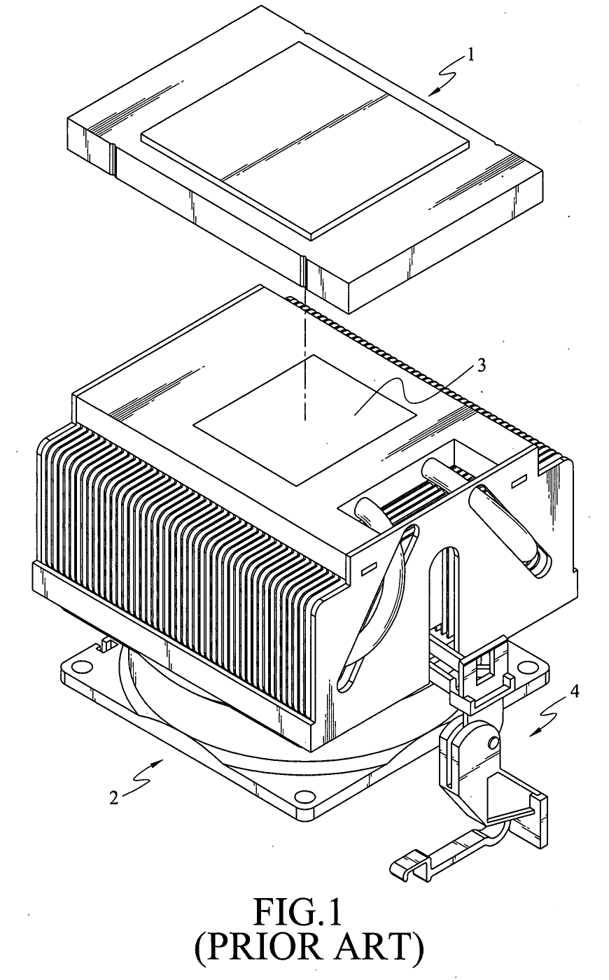

### DETAILED DESCRIPTION OF THE INVENTION

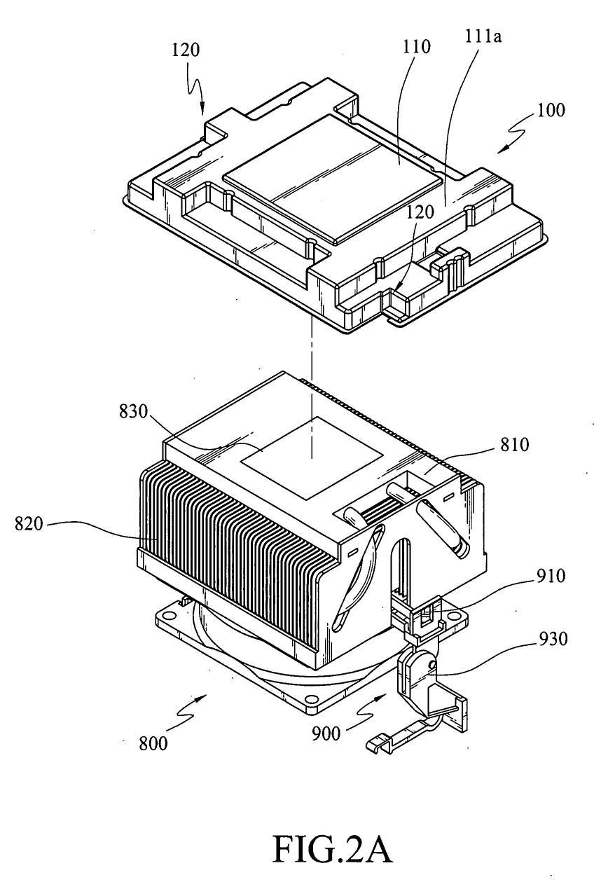

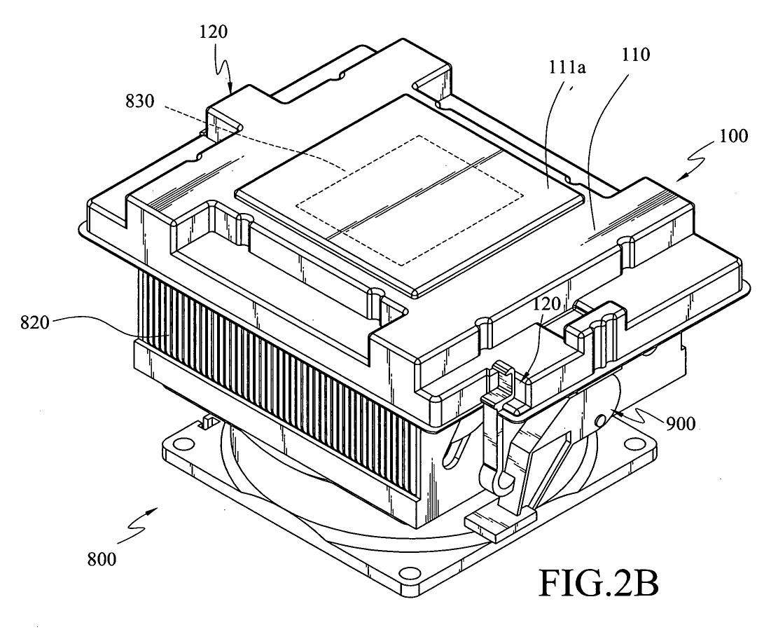

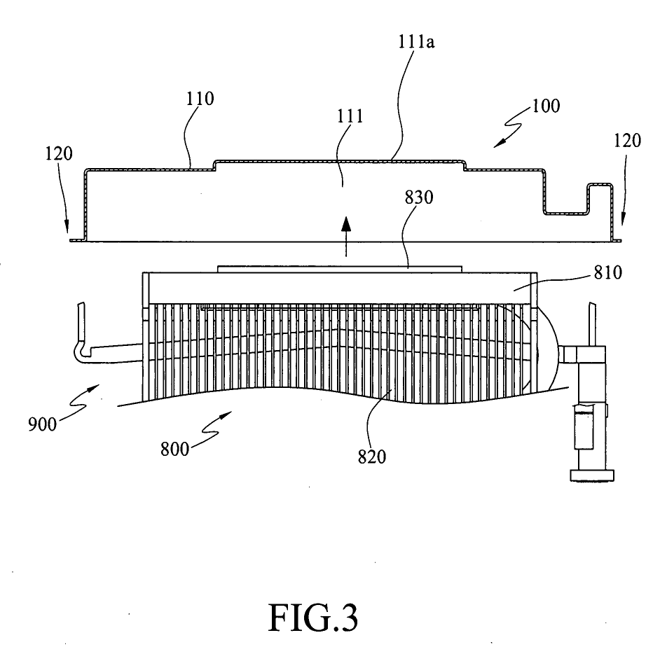

Referring to FIGS. 2A, 2B, and 3, a cover 100 of a first embodiment of the present invention is shown. The cover 100 is covered on the bottom 810 of a heat sink 800, for protecting a thermal conductive medium 830 attached on the bottom 810 of the heat sink 800, thereby preventing the thermal conductive medium 830 from being stained or falling off. The heat sink 800 further includes a heat dissipation portion 820 connected to the bottom 810, for dissipating heat into the air. A latching member 900 is used to press and fix the heat sink 800 to a circuit board (not shown). The latching member 900 spans across the heat dissipation portion 820, and the two ends of the latching member 900 extend toward the bottom 810 of the heat sink 800, so as to latch a counterpart (not shown) on the circuit board, such that the latching member 900 presses and fixed the heat sink 800 onto the circuit board.

Referring to FIGS. 2A, 2B, and 3, the cover 100 includes a tray body 110, and latched portions 120 formed on two opposite lateral edges of the tray body 110. The tray body 110 has an accommodation portion 111, and the area of the horizontal cross-section of the tray body 110 is greater than that of the heat sink 800. The accommodation portion 111 is used to accommodate the bottom 810 of the heat sink 800, such that the tray body 110 is covered on the bottom 810 of the heat sink 800. Meanwhile, a concave base 111a, corresponding to the thermal conductive medium 830, is formed in the accommodation portion 111. When the cover 100 is covered on the bottom 810 of the heat sink 800, the tray body 110 is covered on the bottom 810 of the heat sink 800. The thermal conductive medium 830 is accommodated in the concave base 111a and at a distance from the tray body 110 without contact. Moreover, the two ends of the latching member 900 respectively latch the two latched portions 120, so as to firmly fix the cover 100 to the heat sink 800. The latching member 900 is also fixed, such that the latching member 900 will not shake relative to the heat sink 800, thus avoiding damages to the heat sink 800 caused by the shaking of the latching member 900 during delivery.

The latched portions 120 are designed to fit the configurations of the two ends of the latching member 900, such that the two ends of the latching member 900 respectively latch the corresponding latched portions 120. Different configurations of the latched portion 120 and the corresponding ends of the latching member 900 will be illustrated in detail below.

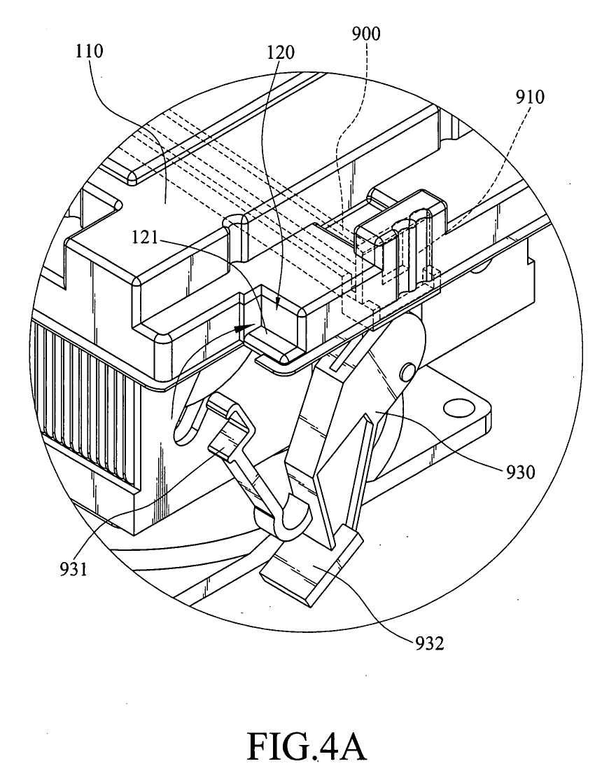

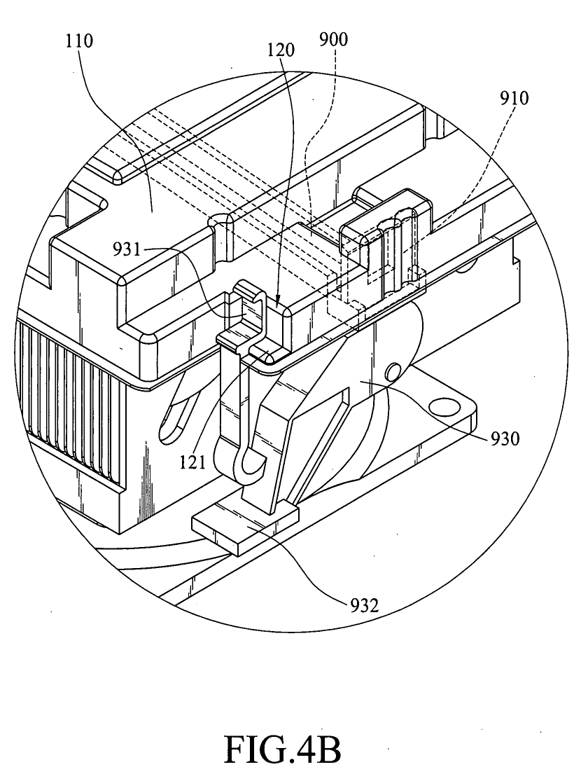

FIGS. 4A and 4B are partial enlarged views showing one end of the latching member 900 and the latched portion 120 on one lateral side of the tray body 110 according to the first embodiment. The end of the latching member 900 has a first latching slab 910 and a handle 930. The first latching slab 910 extends from the end of the latching member 900. The handle 930 is pivotally connected to the latching member 900, and rotates along the long-axis of the latching member 900. The handle 930 has a hook 931 and a hand grip 932 which are monolithically formed with an angle formed there-between.

The latched portion 120 is an indented corner formed on a lateral edge of the tray body 110, and the latched portion 120 includes an extension portion 121 extending from the indented corner. Thus, the handle 930 rotates to make the hook 931 pass through the indented corner and latches the extension portion 121 formed on the outer side surface of the tray body 110, such that the handle 930 will not rotate relatively, and the end of the latching member 900 latches the lateral edge of the tray body 110.

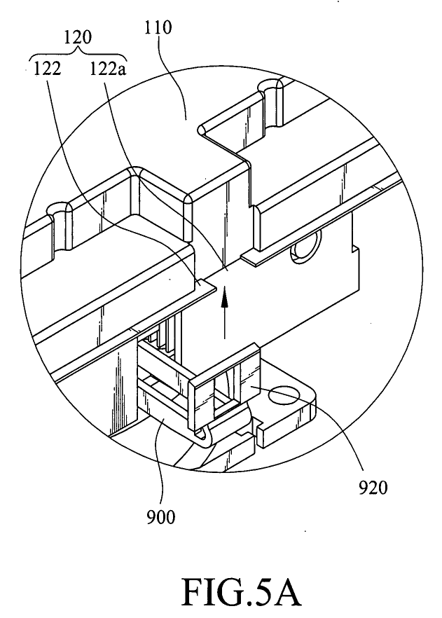

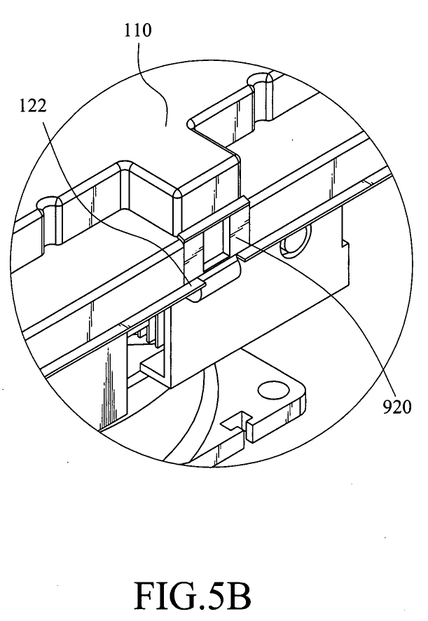

FIGS. 5A and 5B are partial enlarged views showing the other end of the latching member 900 and the latched portion 120 on the other lateral side of the tray body 110 of the first embodiment. The latching member 900 has a second latching slab 920 extending from the other end of the latching member 900. The latched portion 120 is a flange 122 extending from the edge of the tray body 110, and the flange 122 has a notch 122a corresponding to the other end of the latching member. The width of the notch 122a is equal to or slightly greater than that of the latching member 900, and the width of the notch 122a is smaller than that of the second latching slab 920. The second latching slab 920 rests on the outer side of the tray body 110 and is retained in the notch 122a, and the other end of the latching member 900 grasp the latched portion 120 on the lateral edge of the tray body 110.

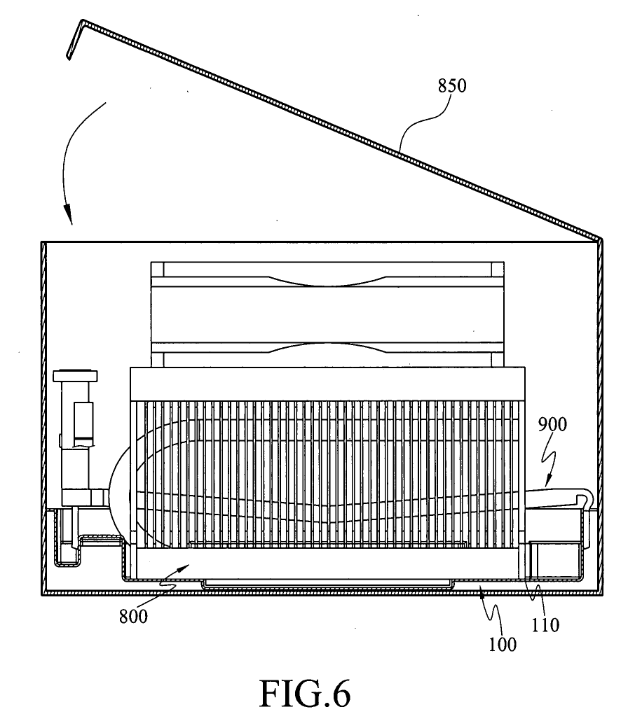

Referring to FIG. 6, the heat sink 800 and the cover 100 are incorporated into a package 850. The package 850 is a container such as a paper box or a plastic box, with a height equal to or slightly higher than that of the heat sink 800. The configuration of the horizontal cross-section of the interior of the package 850 matches the configuration of that of the cover 100, such that the tray body 110 is stably accommodated in the package 850, instead of moving along a transverse-axis direction of the package 850. The tray body 110 of the cover 100 is covered on the bottom of the heat sink 800, and the latching member 900 of the heat sink 800 latches the latched portions 120 of the tray body 110, such that the latching member 900 and the cover 100 are fixed to each other. Through the cover 100 and the package 850, the heat sink 800 is fixed in the package 850 without shaking. Meanwhile, as the area of the horizontal cross-section of the tray body 110 is greater than that of the heat sink, the lateral sides of the heat sink 800 do not contact the package 850, thus producing an isolation buffer effect to prevent the heat sink 800 in the package 850 from being impacted by an external force.

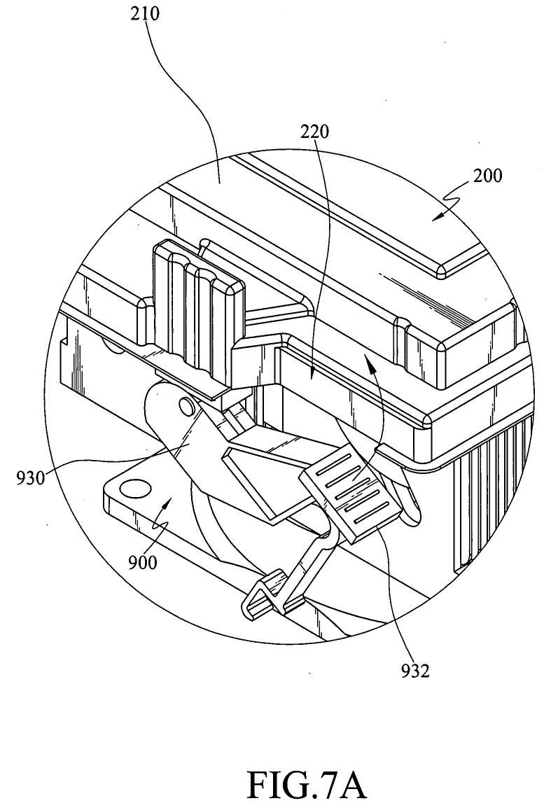

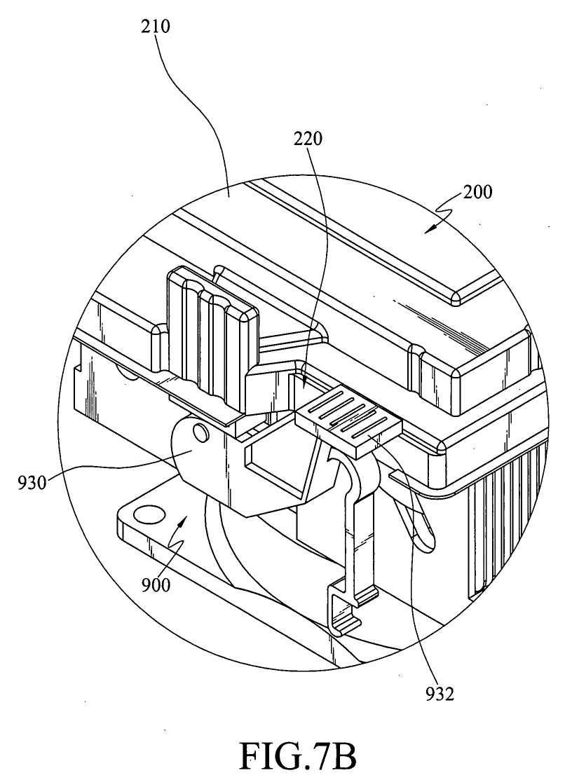

Referring to FIGS. 7A and 7B, a latched portion 220 of a thermal conductive medium cover 200 of a second embodiment of the present invention is shown. The difference between the second embodiment and the first embodiment is described as follows. The latched portion 220 of the second embodiment is an indented corner formed on a lateral edge of a tray body 210, for the hand grip 932 of the handle 930 to pass through. The handle 930 rotates to make the hand grip 932 to pass through the indented corner and latches the outer side surface of the tray body 210, such that one end of the latching member 900 latches the corresponding latched portion 220.

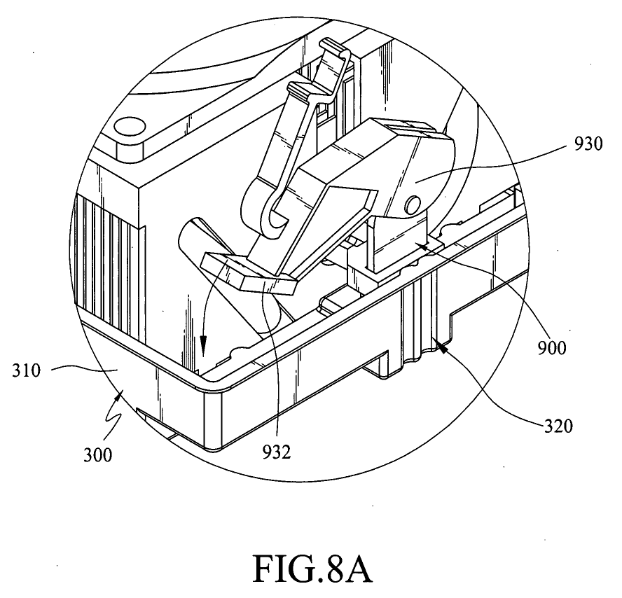

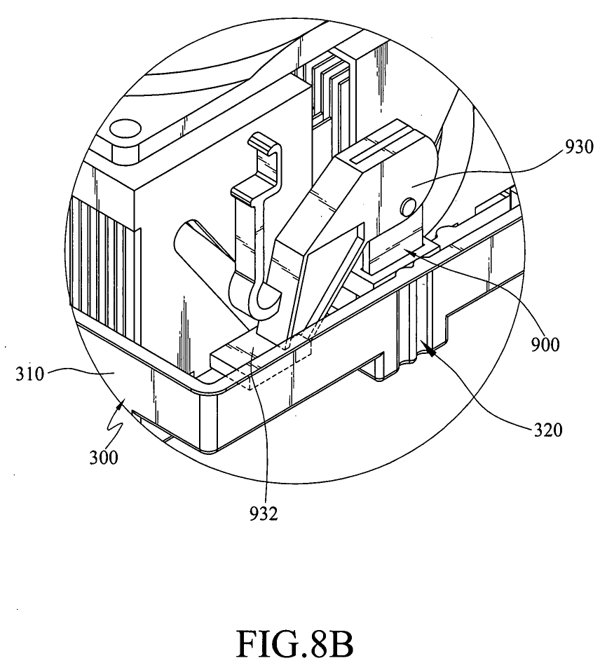

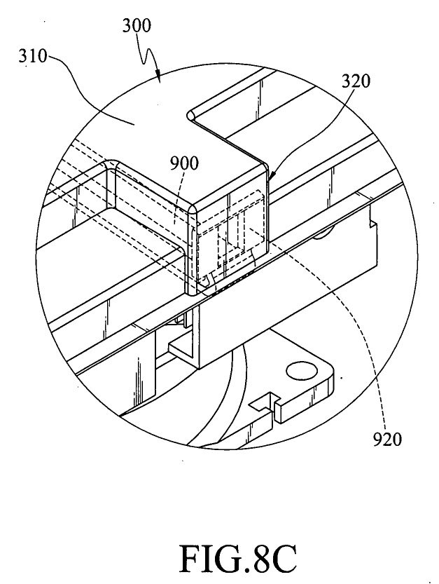

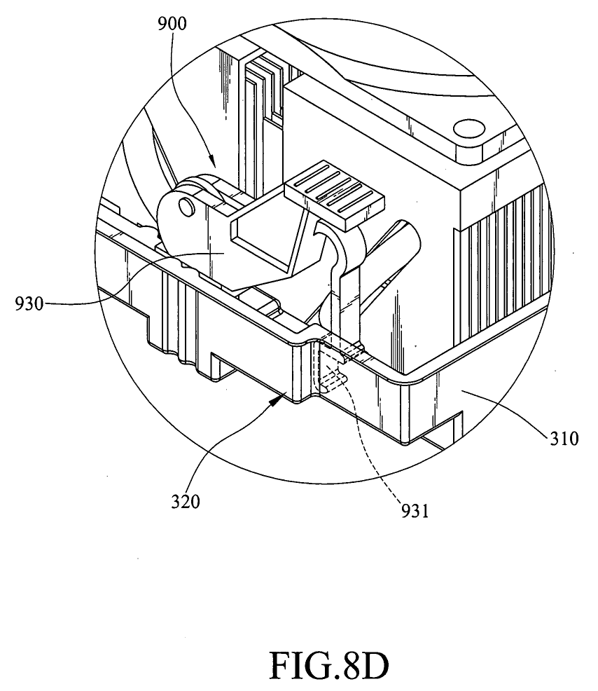

Referring to FIGS. 8A, 8B, and 8C, a thermal conductive medium cover 300 of a third embodiment of the present invention is shown. Latched portions 320 on two lateral sides of a tray body 310 are respectively pressed against the two ends of the latching member 900, so that the two ends of the latching member 900 respectively latched the two latched portions 320 by tight fit. The spacing between the two latched portions 320 is greater than the spacing between the two opposite lateral edges of the tray body 310, and the two ends of the latching member 900 are pressed against the two latched portions 320 from the inner side of the tray body 310.

FIGS. 8A and 8B are partial enlarged views showing one end of the latching member 900 and the latched portion 320 on one lateral side of the tray body 310 of the third embodiment. The latched portion 320 is a handle accommodation region formed on a lateral edge of the tray body 310, for accommodating the handle 930 located on one end of the latching member 900. The handle 930 rotates to make the hand grip 932 pressed against the latched portion 320 from the inner side of the tray body 310, such that one end of the latching member 900 latches the latched portion 320.

FIG. 8C is a partial enlarged view showing the other end of the latching member 900 and the latched portion 320 on the other side of the tray body 310 of the third embodiment. The latched portion 320 is a latching slab accommodation region formed on the other lateral edge of the tray body 310, for accommodating the second latching slab 920. The second latching slab 920 is pressed against the latched portion 320 from the inner side of the tray body 310, such that the other end of the latching member 900 grasp the latched portion 320.

Referring to FIG. 8D, another retaining relation between the handle 930 located at one end of the latching member 900 and the latched portion 320 according to the third embodiment is shown. The handle 930 rotates to make the hook 931 pressed against the latched portion 320 from the inner side of the tray body 310, such that one end of the latching member 900 grasp the latched portion 320.

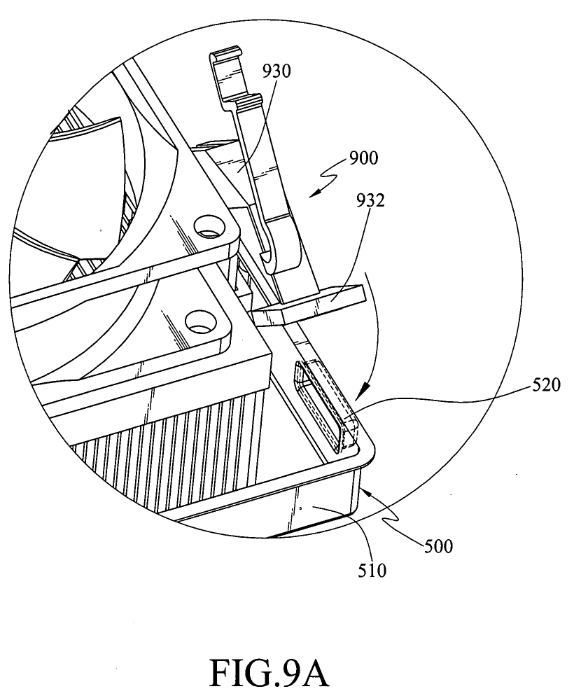

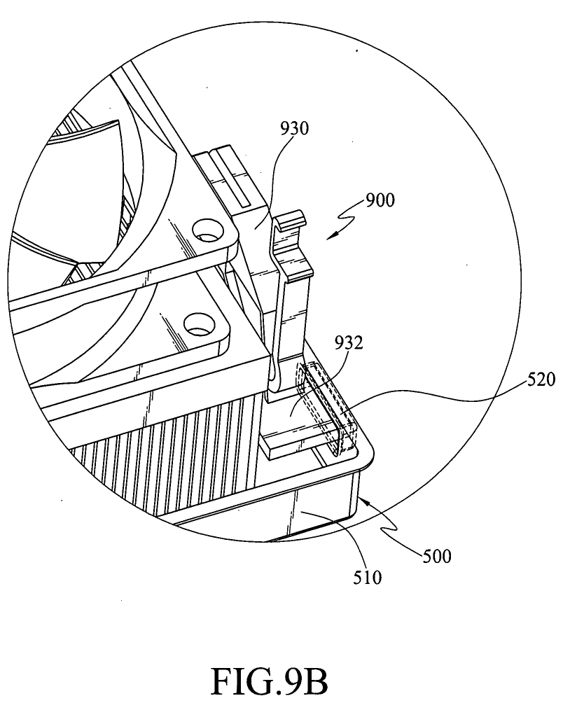

Referring to FIGS. 9A and 9B, a latched portion 520 of a thermal conductive medium cover 500 of a fourth embodiment of the present invention is shown. The latched portion 520 is a depression on one lateral edge of the tray body 510, and the depression is formed on the inner side of the tray body 510, for the hand grip 932 of the handle 930 to be inserted therein, such that the latched portion 520 is latched by the end of the latching member 900.

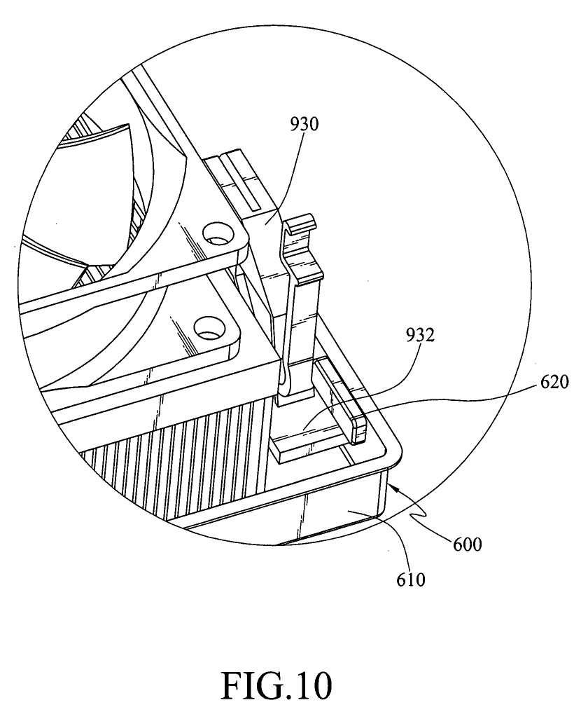

Referring to FIG. 10, a latched portion 620 of a thermal conductive medium cover 600 of a fifth embodiment of the present invention is shown. The latched portion 620 is a bump on a lateral edge of the tray body 610. The bump is formed on the inner side of the tray body 610, for the hand grip 932 of the handle 930 to latch, such that the latched portion 620 is grasped by one end of the latching member 900.

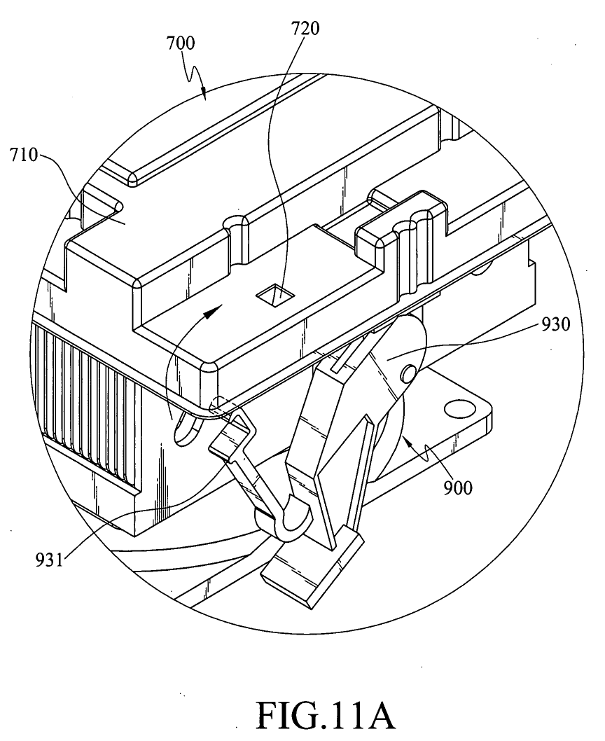

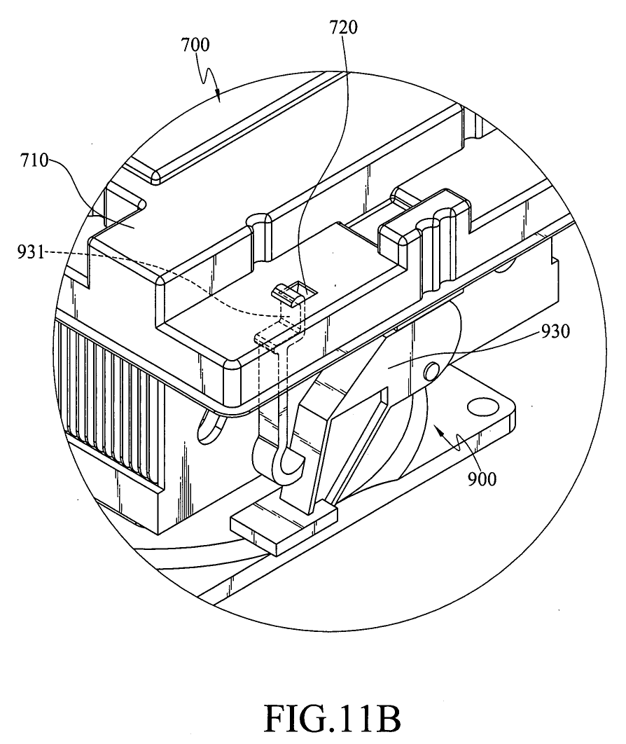

Referring to FIGS. 11A and 11B, a latched portion 720 of a thermal conductive medium cover 700 of a sixth embodiment of the present invention is shown. The latched portion 720 is a hook hole formed in the tray body 710, for the hook 931 of the handle 930 to hook, such that the latched portion 720 is latched by one end of the latching member 900.

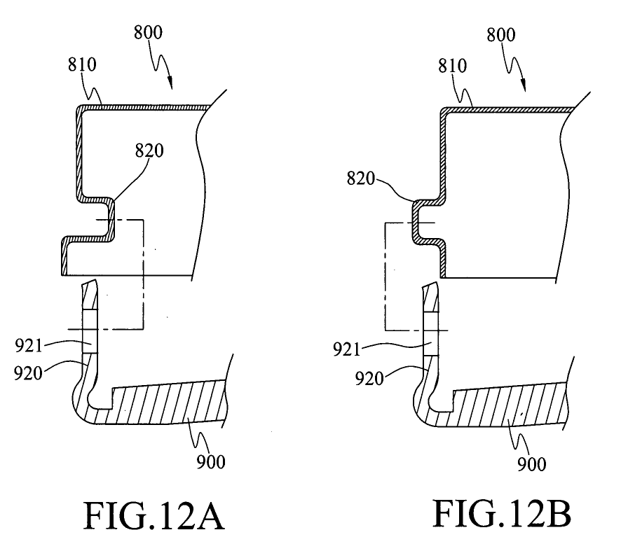

FIGS. 12A and 12B show a thermal conductive medium cover 800 of a seventh embodiment of the present invention, in which the engagement manner between the second latching slab 920 at the other end of the latching member 900 and the latched portion 820 is changed. The latched portion 820 is a bump formed on a lateral edge of the tray body 810, for being inserted in a second locking hole 921 of the second latching slab 920. The bump may be formed on the inner side of the tray body 810, as shown in FIG. 12A, or formed on the outer side of the tray body 810, as shown in FIG. 12B.

According to the present invention, latched structures corresponding to the two ends of the latching member are formed on two opposite lateral sides of the tray body, such that when the tray body is covered on the bottom of the heat sink, the two ends of the latching member latch the two opposite lateral edges of the tray body, thus preventing the tray body from falling off, and meanwhile the latching member will not shake to collide with the latching member.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A thermal conductive medium cover, covered on a bottom of a heat sink for protecting a thermal conductive medium on the bottom of the heat sink, and fixed by a latching member for the heat sink, the thermal conductive medium cover comprising:
a tray body, covered on the bottom of the heat sink; and
two latched portions, formed on two opposite lateral edges of the tray body, wherein two ends of the latching member respectively latch the two latched portions, so as to fix the tray body to the bottom of the heat sink.

2. The thermal conductive medium cover as claimed in claim 1, wherein each of the latched portions is an indented corner formed on a lateral edge of the tray body, for one end of the latching member to pass through to latch an outer side surface of the tray body.

3. The thermal conductive medium cover as claimed in claim 2, wherein each of the latched portions further comprises an extension portion extending from the indented corner, for the end of the latching member to latch.

4. The thermal conductive medium cover as claimed in claim 1, wherein each of the latched portions is a flange extending from the edge of the tray body, and the flange has a notch corresponding to one end of the latching member, such that the end of the latching member latches in the notch.

5. The thermal conductive medium cover as claimed in claim 1, wherein each of the latched portions is pressed against one end of the latching member, so as to be latched by the end of the latching member.

6. The thermal conductive medium cover as claimed in claim 5, wherein one end of the latching member is pressed against the latched portion from an inner side of the tray body.

7. The thermal conductive medium cover as claimed in claim 1, wherein the latched portion is a bump formed on the tray body, so as to be latched by one end of the latching member.

8. The thermal conductive medium cover as claimed in claim 7, wherein the bump is formed on the inner side of the tray body.

9. The thermal conductive medium cover as claimed in claim 7, wherein the bump is formed on the outer side of the tray body.

10. The thermal conductive medium cover as claimed in claim 1, wherein the latched portion is a depression formed on a lateral edge of the tray body, for one end of the latching member to be inserted therein.

11. The thermal conductive medium cover as claimed in claim 10, wherein the depression is formed on the inner side of the tray body.

12. The thermal conductive medium cover as claimed in claim 1, wherein the latched portion is a hook hole formed in the tray body, for one end of the latching member to hook.

13. The thermal conductive medium cover as claimed in claim 1, wherein the tray body has an accommodation portion for accommodating the bottom of the heat sink, and a concave base is further formed in the accommodation portion, when the tray body is covered on the bottom of the heat sink, the thermal conductive medium is accommodated in the concave base and at a distance from the tray body.
